(19) United States
(12) Patent Application Publication
(10) Pub. No.: US 2024/0170084 A1
(43) Pub. Date: May 23, 2024

(54) SEMICONDUCTOR DEVICE, VEHICLE-MOUNTED APPARATUS, AND CONSUMER APPARATUS

(71) Applicant: Rohm Co., Ltd., Kyoto (JP)

(72) Inventors: Hiromitsu KIMURA, Kyoto (JP); Tomokazu Okada, Kyoto (JP); Yuji KUROTSUCHI, Kyoto (JP)

(21) Appl. No.: 18/427,383

(22) Filed: Jan. 30, 2024

Related U.S. Application Data
(63) Continuation of application No. PCT/JP2022/023922, filed on Jun. 15, 2022.

(30) Foreign Application Priority Data
Jul. 30, 2021 (JP) 2021-125941

(51) Int. Cl. G11C 29/12; B60W 50/04

(52) U.S. Cl. CPC G11C 29/1201; B60W 50/04; B60W 2050/041

(57) ABSTRACT

A semiconductor device includes, for example, internal circuitry (for example, a CPU), external terminals (for example, debug control terminals of the CPU) configured to be used by the internal circuitry in a non-test mode (for example, a debug mode of the CPU), and a test circuit configured to, upon detecting that a particular dedicated test mode control pattern has been inputted to the external terminals, cause a transition from the non-test mode to a test mode.

### CROSS-REFERENCE TO RELATED APPLICATIONS

This nonprovisional application is a continuation application of International Patent Application No. PCT/JP2022/023922 filed on Jun. 15, 2022, which claims priority Japanese Patent Application No. 2021-125941 filed on Jul. 30, 2021, the entire contents of which are hereby incorporated by reference.

### TECHNICAL FIELD

The invention disclosed in the present description relates to a semiconductor device and a vehicle-mounted apparatus and a consumer apparatus that use the semiconductor device.

### BACKGROUND ART

There are conventionally known semiconductor devices equipped with a self-diagnosis function (a so-called BIST [built-in self test] function).

An example of a conventional technique related to the above can be seen in Patent Document 1.

### CITATION LIST

### Patent Literature

Patent Document 1: JP-A-2021-050924

### BRIEF DESCRIPTION OF DRAWINGS

FIG. 1 is a view showing a configuration example of an application using a semiconductor device.

FIG. 2 is a view showing a first embodiment of the semiconductor device.

FIG. 3 is a view showing an example of a dedicated test mode control pattern in the first embodiment.

FIG. 4 is a view showing a first factor.

FIG. 5 is a view showing a second factor.

FIG. 6 is a view showing a third factor.

FIG. 7 is a view showing a disadvantage of the first embodiment.

FIG. 8 is a view showing a second embodiment of the semiconductor device.

FIG. 9 is a view showing an example of a dedicated test mode control pattern in the second embodiment.

FIG. 10 is a view showing improvements that have been made in the dedicated test mode control pattern.

### DESCRIPTION OF EMBODIMENTS

### <Semiconductor Device (Application)>

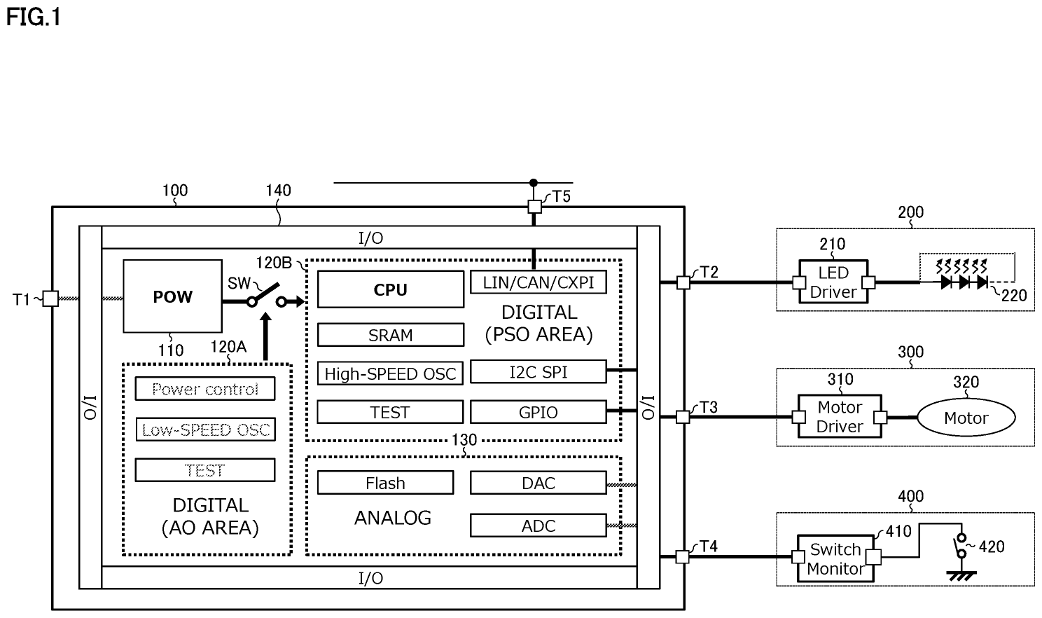

FIG. 1 is a view showing a configuration example of an application using a semiconductor device. A semiconductor device 100 of this configuration example is a unified communication IC designed to be vehicle-mounted for controlling, in accordance with commands received via a vehicle-mounted network, controllers (ECUs [electronic control units] and so on) mounted in various types of terminal devices. The semiconductor device 100 includes a plurality of external terminals T1 to T5 as tools for establishing electrical connection with an exterior of the device.

The external terminal T1 is a power supply terminal that accepts supply of power from a battery. The external terminals T2 to T4 are communication terminals for sending and receiving signals between themselves and various types of terminal devices (for example, an LED [light emitting diode] light emitting device 200, a motor device 300, and a switch device 400), respectively, by use of any given protocol (an I2C [inter-integrated circuit], an SPI [serial peripheral interface], a GPIO [general-purpose input/output], a PWM [pulse width modulation], and so on). The external terminal T5 is a network terminal connected to any given vehicle-mounted network (a LIN [local interconnect network], a CXPI [clock extension peripheral interface], a CAN [controller area network], and so on).

The LED light emitting device 200 includes an LED 220 and an LED driver IC 210 that controls light emission driving of the LED 220 in accordance with a command from the semiconductor device 100.

The motor device 300 includes a motor 320 and a motor driver IC 310 that controls rotation driving of the motor 320 in accordance with a command from the semiconductor device 100.

The switch device 400 includes a switch 420 and a switch monitor IC 410 that monitors an open/close state of the switch 420 and notifies the semiconductor device 100 of a detection result.

With continued reference to FIG. 1, a description is given of an internal configuration of the semiconductor device 100. The semiconductor device 100 of this configuration example includes a power supply circuit 110, a digital circuit 120 (in this figure, digital circuits 120A and 120B), an analog circuit 130, an I/O [input/output] circuit 140, and a power supply switch SW.

The power supply circuit 110 generates a predetermined internal power supply voltage from a battery voltage applied to the external terminal T1 and supplies the internal power supply voltage to each of various portions of the semiconductor device 100. Circuit blocks integrated in the semiconductor device 100 belong to either an AO [always ON] area or a PSO [partial shut-OFF] area. The AO area is an area where a power-on state is always maintained regardless of whether the semiconductor device 100 is in a normal mode (=corresponding to a first operation mode) or in a standby mode (=a second operation mode). The PSO area, on the other hand, is an area provided downstream of the power supply switch SW, where the power-on state is brought about when the semiconductor device 100 is in the normal mode (SW=ON) and a power-off state is brought about when the semiconductor device 100 is in the standby mode (SW=OFF). Needless to say, the power supply circuit 110 is mounted in the AO area.

The digital circuit 120A is one of the circuit blocks mounted in the AO area and includes a power supply controller, a low-speed oscillator, a part of a test circuit, and so on.

The digital circuit 120B is one of the circuit blocks mounted in the PSO area and includes a CPU [central processing unit], a SRAM [static random access memory], a high-speed oscillator, a part of the test circuit, a LIN/CAN/CXPI interface, an I2C/SPI interface, a GPIO interface, and so on.

The analog circuit 130 includes a flash memory, a DAC [digital-to-analog converter], an ADC [analog-to-digital converter], and so on. The analog circuit 130 may be mounted in the AO area or the PSO area.

The I/O circuit 140 is a front-end circuit that sends and receives signals between the external terminals T1 to T5 and internal circuitry (the power supply circuit 110, the digital circuits 120A and 120B, and the analog circuit 130). In a plan view of the semiconductor device 100, the I/O circuit 140 may be disposed along four sides of the semiconductor device 100 so as to enclose the above-described internal circuitry.

Based on a command from the digital circuit 120A (particularly, the power supply controller), the power supply switch SW brings a path for supplying power from the power supply circuit 110 to the PSO area into or out of electrical conduction.

### Semiconductor Device (First Embodiment)

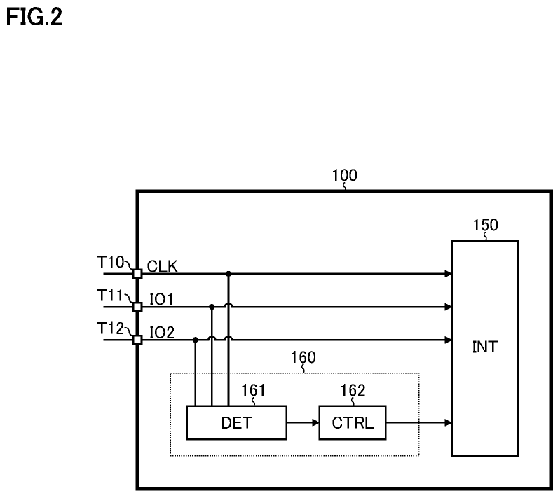

FIG. 2 is a view showing a first embodiment of the semiconductor device 100. A semiconductor device 100 of the present embodiment includes internal circuitry 150, a test circuit 160, and external terminals T10 to T12.

The internal circuitry 150 is, for example, a CPU that operates in synchronism with a clock signal CLK inputted via the external terminal T10. The internal circuitry 150, however, is not limited to the CPU and may be any other digital circuit or analog circuit.

The external terminals T11 and T12 are primarily to be used by the internal circuitry 150 when the semiconductor device 100 is in a non-test mode, and input/output signals IO1 and IO2 are applied thereto, respectively. For example, the external terminals T11 and T12 may be used as debug control terminals for inputting and outputting debug signals in a debug mode of the CPU. The debug signals are input/output signals for directly controlling the internal circuitry 150 from an exterior of the semiconductor device 100.

Furthermore, in causing a transition of the semiconductor device 100 from the non-test mode to a test mode, a particular dedicated test mode control pattern (details thereof will be described later) not to be inputted in a normal operation is inputted to the external terminals T11 and T12. In the test mode, there is no need for directly controlling the internal circuitry 150 from the exterior of the semiconductor device 100. Accordingly, no particular problem arises even when the external terminals T11 and T12 are used also as input terminals for inputting the dedicated test mode control pattern.

The test circuit 160 is a circuit block that operates in synchronism with the clock signal CLK inputted through the external terminal T10 and governs a self-diagnosis function for the various portions of the device when the semiconductor device 100 is in the test mode, and includes a pattern detection portion 161 and a test control portion 162.

The pattern detection portion 161 detects whether or not the particular dedicated test mode control pattern has been inputted to the external terminals T11 and T12.

Upon the dedicated test mode control pattern being detected in the pattern detection portion 161, the test control portion 162 causes the transition from the non-test mode to the test mode and performs a self-diagnosis of the various portions of the device (for example, the internal circuitry 150).

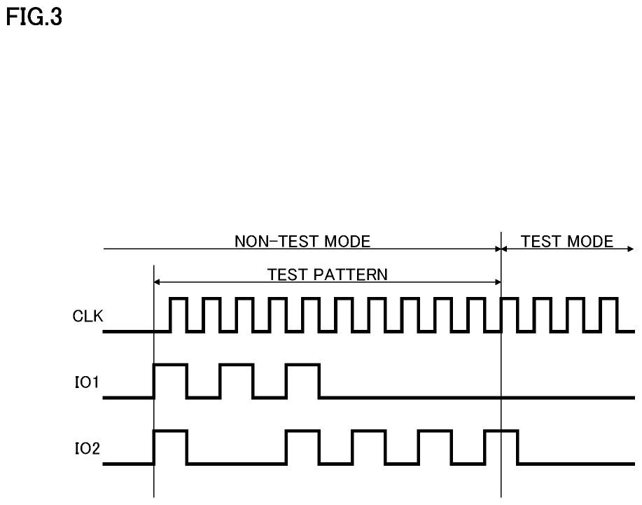

FIG. 3 is a view showing an example of the dedicated test mode control pattern in the first embodiment, in which the clock signal CLK and the input/output signals IO1 and IO2 are depicted in order from top to bottom.

In the example shown in this figure, the input/output signal IO1 has three pulses successively generated in synchronism with the clock signal CLK. The input/output signal IO2, on the other hand, has two pulses generated also in synchronism with the clock signal CLK at the same timings as generation timings of the first and third pulses of the input/output signal IO1 and three more pulses successively generated to follow the two pulses.

Upon recognizing a combination of pulse trains described above, the test circuit 160 determines that the dedicated test mode control pattern (in the figure, abbreviated as “TEST PATTERN”) has been inputted. As a result, the semiconductor device 100 makes the transition from the non-test mode to the test mode.

As described above, in the semiconductor device 100 of the present embodiment, the test circuit 160 is equipped with a function of, upon detecting that the particular dedicated test mode control pattern has been inputted to the external terminals T11 and T12, causing the transition from the non-test mode to the test mode.

Accordingly, without the need for separately providing a dedicated test mode control external terminal, the transition from the non-test mode to the test mode can be caused by using the existing external terminals T11 and T12 also for this purpose, and thus it becomes possible to reduce the number of pins and a chip area of the semiconductor device 100.

### Disadvantage of First Embodiment

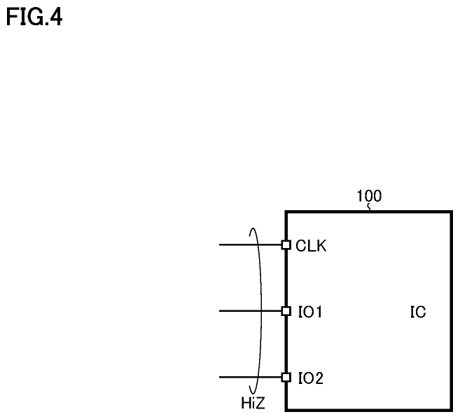

FIG. 4 to FIG. 6 are views showing factors responsible for occurrence of an accidentally occurring dedicated test mode control pattern in the input/output signals IO1 and IO2.

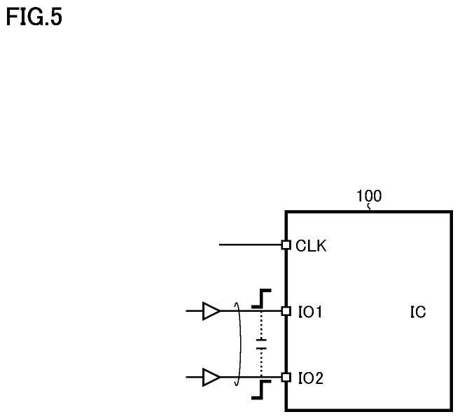

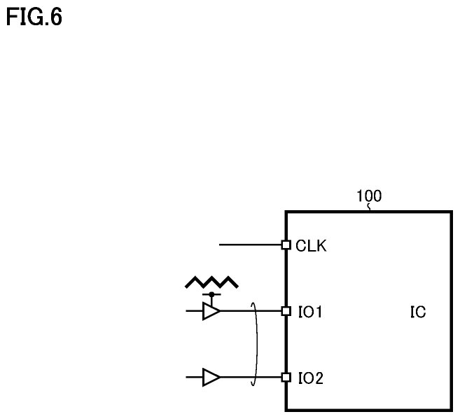

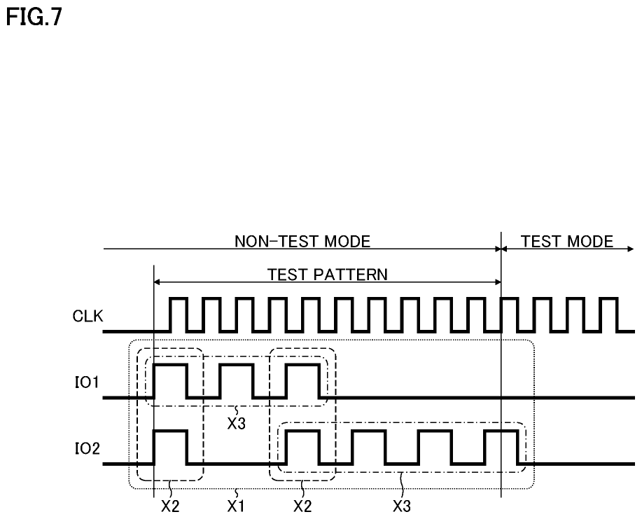

Furthermore, FIG. 7 is a view showing a disadvantage as to the dedicated test mode control pattern in the first embodiment, in which, similarly to FIG. 3 referred to above, the clock signal CLK and the input/output signals IO1 and IO2 are depicted in order from top to bottom. In this figure, a short dashed line frame X1, long dashed line frames X2, and single-dashed chain line frames X3 indicate parts where an erroneous pulse may occur due to a first factor (FIG. 4), a second factor (FIG. 5), and a third factor (FIG. 6), respectively.

For example, when, as shown in FIG. 4, the external terminals T11 and T12 turn into a high impedance state (=a floating state where an electrical potential thereof is not fixed), a random erroneous pulse may occur in the input/output signals IO1 and IO2 due to noise or the like.

Furthermore, in a case where, as shown in FIG. 5, signal wiring lines connected to the external terminals T11 and T12 are in proximity to each other and buffers provided on the signal wiring lines have relatively small current drivability, an erroneous pulse may occur due to coupling noise between the signal wiring lines. Specifically, a change in logic level of one of the input/output signals IO1 and IO2 might cause the other of the input/output signals IO1 and IO2 also to change in logic level correspondingly thereto.

Moreover, in a case where, as shown in FIG. 6, power for the buffers periodically fluctuates, a periodic erroneous pulse may occur also in the input/output signals IO1 and IO2.

When the above-described three factors (FIG. 4 to FIG. 6) unfortunately occur at one time, an accidentally occurring dedicated test mode control pattern may occur in the input/output signals IO1 and IO2. Consequently, in the above-described first embodiment, there is a risk of incurring an unintended transition of the semiconductor device 100 to the test mode, thus failing to execute a desired operation.

Furthermore, in the event that the semiconductor device 100 has accidentally made a transition to the test mode, the above-described first embodiment includes no mechanism for enabling the semiconductor device 100 to return by itself from the test mode to the non-test mode.

The following proposes a second embodiment capable of solving such inconvenience.

### Semiconductor Device (Second Embodiment)

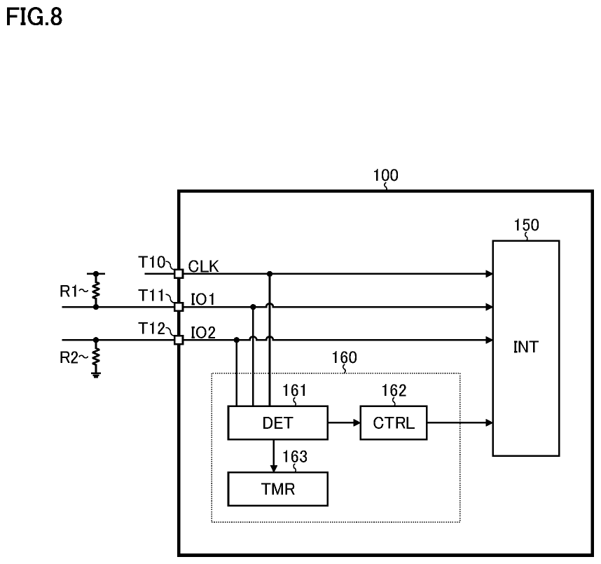

FIG. 8 is a view showing the second embodiment of the semiconductor device 100. A semiconductor device 100 of the present embodiment has a configuration based on that of the above-described first embodiment (FIG. 2), to which several modifications have been made.

First, as a modification to an external configuration, an external terminal T11 is formed of a pull-up terminal, and an external terminal T12 is formed of a pull-down terminal. That is, the external terminal T11 is pulled up to a power supply terminal via an external resistor R1. The external terminal T12, on the other hand, is pulled down to a ground terminal via an external resistor R2.

Furthermore, as a modification to an internal configuration, a timer circuit 163 for detecting whether or not a dedicated test mode control pattern has been periodically inputted is newly incorporated into a test circuit 160.

Moreover, in the semiconductor device 100 of the present embodiment, various modifications have been made also to the dedicated test mode control pattern itself (details thereof will be described later).

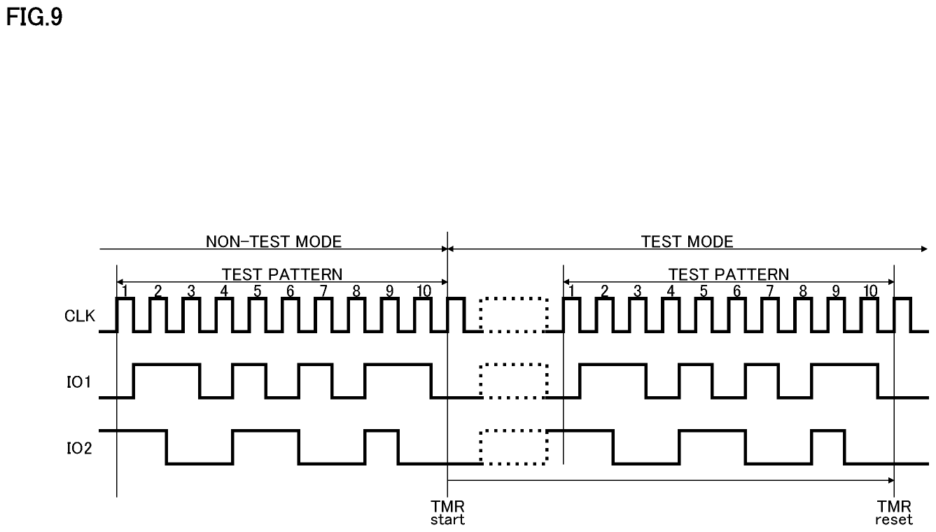

FIG. 9 is a view showing an example of the dedicated test mode control pattern in the second embodiment, in which, similarly to FIG. 3 referred to above, a clock signal CLK and input/output signals IO1 and IO2 are depicted in order from top to bottom. In the following description, for the sake of convenience, pulses of the clock signal CLK, which are generated during an input period of the test mode control pattern, are sequentially numbered and referred to as a first pulse, a second pulse, . . . and a tenth pulse.

In the example shown in this figure, the input/output signal IO1 turns to a high level in synchronism with the first pulse (for example, at a falling edge thereof, the same applies hereinafter) of the clock signal CLK, to a low level in synchronization with the third pulse, to the high level in synchronism with the fourth pulse, to the low level in synchronism with the fifth pulse, to the high level in synchronism with the sixth pulse, to the low level in synchronism with the seventh pulse, to the high level in synchronism with the eighth pulse, and to the low level in synchronism with the tenth pulse.

The input/output signal IO2, on the other hand, turns to a low level in synchronism with the second pulse, to a high level in synchronism with the fourth pulse, to the low level in synchronism with the sixth pulse, to the high level in synchronism with the eighth pulse, and to the low level in synchronism with the ninth pulse.

Upon recognizing a combination of pulse trains described above, the test circuit 160 determines that the dedicated test mode control pattern (in the figure, abbreviated as “TEST PATTERN”) has been inputted. As a result, the semiconductor device 100 makes a transition from the non-test mode to the test mode.

Furthermore, the test circuit 160 is also equipped with a function of, upon detecting that, after the transition to the test mode, the above-described dedicated test mode control pattern has not been periodically inputted, causing a return from the test mode to the non-test mode (details thereof will be described later).

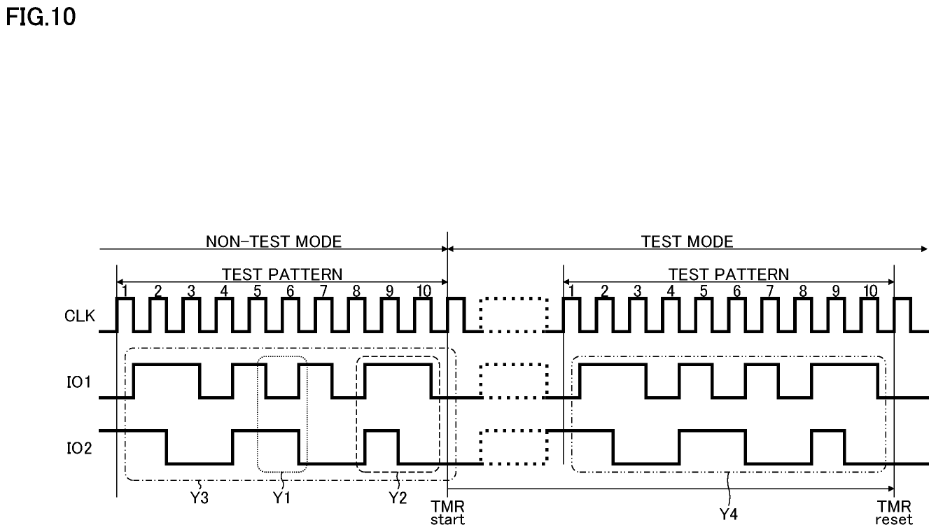

FIG. 10 is a view showing improvements that have been made in the dedicated test mode control pattern in the second embodiment, in which, similarly to FIG. 9 referred to above, the clock signal CLK and the input/output signals IO1 and IO2 are depicted in order from top to bottom. In this figure, a short dashed line frame Y1, a long dashed line frame Y2, a single-dashed chain line frame Y3, and a double-dashed chain line frame Y4 indicate first to fourth improvements, respectively.

The first improvement is intended to avoid an influence of an erroneous pulse that may occur due to the first factor described earlier (FIG. 4). As shown by the short dashed line frame Y1 in this figure, the dedicated test mode control pattern includes a signal pattern in which a low-level voltage is applied as the input/output signal IO1 applied to the external terminal T11 (=the pull-up terminal). Contrary thereto, the dedicated test mode control pattern also includes a signal pattern in which a high-level voltage is applied as the input/output signal IO2 applied to the external terminal T12 (=the pull-down terminal). According to such an improvement, in no case is the above-described dedicated test mode control pattern established unless a host purposely switches respective logic levels of the input/output signals IO1 and IO2 in a direction opposite to a pull-up/pull-down direction.

The second improvement is intended to avoid an influence of an erroneous pulse that may occur due to the second factor described earlier (FIG. 5). As shown by the long dashed line frame Y2 in this figure, the dedicated test mode control pattern includes a signal pattern in which only either one of the respective logic levels of the external terminals T11 and T12 is switched at a given timing. With reference to this figure, while the input/output signals IO1 and IO2 simultaneously turn to a high level in synchronism with the eighth pulse of the clock signal CLK, at a timing when the ninth pulse falls, only the input/output signal IO2 turns to a low level, and the input/output signal IO1 is maintained at the high level. Since in a case of the erroneous pulse occurring due to coupling noise between signal wiring lines, the respective logic levels of the input/output signals IO1 and IO2 should both change in the same manner, in no case is the above-described dedicated test mode control pattern established.

The third improvement is intended to avoid an influence of an erroneous pulse that may occur due to the third factor described earlier (FIG. 6). As shown by the single-dashed chain line frame Y3 in this figure, the dedicated test mode control pattern employed is a pattern with a non-constant pulse cycle. In other words, a particular repetitive pattern (for example, a pattern in which high and low levels repeatedly appear at constant intervals) is excluded from the dedicated test mode control pattern. According to such an improvement, even when the power for the buffers periodically fluctuates, in no case is the above-described dedicated test mode control pattern established.

It can be said that the possibility of accidental occurrence of a test mode setting pattern in which these improvements have been made is extremely low. Accordingly, it becomes possible to improve reliability (quality) of the semiconductor device 100 by avoiding an unintended transition to the test mode while reducing the number of pins and the chip area of the semiconductor device 100.

Furthermore, as the fourth improvement, the test circuit 160 is also equipped with the function of, upon detecting that, after the transition to the test mode, the above-described dedicated test mode control pattern has not been periodically inputted, causing a return from the test mode to the non-test mode (see the double-dashed chain line frame Y4 in this figure).

With reference to this figure, after the transition to the test mode, the test circuit 160 controls the timer circuit 163 to start a counting operation, and at a timing of detection that the dedicated test mode control pattern has been inputted again, resets a count value of the timer circuit 163 to an initial value (for example, 0).

Accordingly, as long as, after the transition to the test mode, the dedicated test mode control pattern is periodically inputted, the count value of the timer circuit 163 is reset before reaching a predetermined threshold value. In this case, the semiconductor device 100 is maintained in the test mode.

On the other hand, in a case where, after the transition to the test mode, no dedicated test mode control pattern is inputted, the count value of the timer circuit 163 reaches the predetermined threshold value without being rest. In this case, the semiconductor device 100 returns from the test mode to the non-test mode.

With such a safety mechanism provided, even in the event that an accidentally occurring dedicated test mode control pattern occurs to cause an unintended transition of the semiconductor device 100 to the test mode, unless the dedicated test mode control pattern is periodically inputted, there is caused an automatic transition out of the test mode into the non-test mode, and thus the normal operation of the semiconductor device 100 is prevented from being obstructed.

### <Uses>

While each being directed to a vehicle-mounted apparatus as an example, without any limitation thereto, the above-described various embodiments are applicable to and widely usable in a suitable manner also for various electronic apparatuses (such as battery-driven consumer apparatuses).

### <Overview>

To follow is an overview of the above-described various embodiments.

For example, the semiconductor device disclosed in the present description has a configuration (a first configuration) including internal circuitry, an external terminal configured to be used by the internal circuitry in a non-test mode, and a test circuit configured to, upon detecting that a particular dedicated test mode control pattern has been inputted to the external terminal, cause a transition from the non-test mode to a test mode.

The semiconductor device according to the above-described first configuration may have a configuration (a second configuration) in which the external terminal includes a pull-up terminal, and the dedicated test mode control pattern includes a signal pattern in which a low-level voltage is applied to the pull-up terminal.

Furthermore, the semiconductor device according to the above-described first or second configuration may have a configuration (a third configuration) in which the external terminal includes a pull-down terminal, and the dedicated test mode control pattern includes a signal pattern in which a high-level voltage is applied to the pull-down terminal.

Furthermore, the semiconductor device according to any of the above-described first to third configurations may have a configuration (a fourth configuration) in which the external terminal includes a first external terminal and a second external terminal, and the dedicated test mode control pattern includes a signal pattern in which only either one of respective logic levels of the first external terminal and the second external terminal is switched at a given timing.

Furthermore, the semiconductor device according to the above-described fourth configuration may have a configuration (a fifth embodiment) in which signal wiring lines connected to the first external terminal and the second external terminal are in proximity to each other.

Furthermore, the semiconductor device according to any of the above-described first to fifth configurations may have a configuration (a sixth configuration) in which the dedicated test mode control pattern is a pattern with a non-constant pulse cycle.

Furthermore, the semiconductor device according to any of the above-described first to sixth configurations may have a configuration (a seventh configuration) in which, upon detecting that the dedicated test mode control pattern has not been periodically inputted, the test circuit causes a return from the test mode to the non-test mode.

Furthermore, the semiconductor device according to any of the above-described first to seventh configurations may have a configuration (an eighth configuration) in which the internal circuitry is a CPU, and the external terminal is a debug control terminal of the CPU.

Furthermore, the vehicle-mounted apparatus disclosed in the present description has a configuration (a ninth configuration) including the semiconductor device according to any of the above-described first to eighth configurations.

Furthermore, the consumer apparatus disclosed in the present description has a configuration (a tenth configuration) including the semiconductor device according to any of the above-described first to eighth configurations.

### Other Modification Examples

Besides the foregoing embodiments, the various technical features disclosed in the present description may be modified in different ways without departing from the gist of technical creation thereof. That is, the foregoing embodiments are to be construed in all respects as illustrative and not limiting. It is to be understood that the technical scope of the present invention is not limited to the foregoing embodiments, and all changes that come within the meaning and range of equivalency of the claims are intended to be embraced therein.

1. A semiconductor device, comprising:
internal circuitry;
an external terminal configured to be used by the internal circuitry in a non-test mode; and
a test circuit configured to, upon detecting that a particular dedicated test mode control pattern has been inputted to the external terminal, cause a transition from the non-test mode to a test mode.

2. The semiconductor device according to claim 1, wherein
the external terminal includes a pull-up terminal, and
the dedicated test mode control pattern includes a signal pattern in which a low-level voltage is applied to the pull-up terminal.

3. The semiconductor device according to claim 1, wherein
the external terminal includes a pull-down terminal, and
the dedicated test mode control pattern includes a signal pattern in which a high-level voltage is applied to the pull-down terminal.

4. The semiconductor device according to 1, wherein
the external terminal includes a first external terminal and a second external terminal, and
the dedicated test mode control pattern includes a signal pattern in which only either one of respective logic levels of the first external terminal and the second external terminal is switched at a given timing.

5. The semiconductor device according to claim 4, wherein
signal wiring lines connected to the first external terminal and the second external terminal are in proximity to each other.

6. The semiconductor device according to claim 1, wherein
the dedicated test mode control pattern is a pattern with a non-constant pulse cycle.

7. The semiconductor device according to claim 1, wherein
upon detecting that the dedicated test mode control pattern has not been periodically inputted, the test circuit causes a return from the test mode to the non-test mode.

8. The semiconductor device according to claim 1, wherein
the internal circuitry is a CPU, and
the external terminal is a debug control terminal of the CPU.

9. A vehicle-mounted apparatus, comprising:
the semiconductor device according to claim 1.

10. A consumer apparatus, comprising:
the semiconductor device according to claim 1.
